(19) United States
(12) Patent Application Publication
(10) Pub. No.: US 2010/0132790 A1
(43) Pub. Date: Jun. 3, 2010

(54) Rechargeable Dye Sensitized Solar Cell

(75) Inventor: Nabil M. Lawandy, Saunderstown, RI (US)

Correspondence Address: K&L Gates LLP, STATE STREET FINANCIAL CENTER, One Lincoln Street, BOSTON, MA, 02111-2950, US

(73) Assignee: SOLARIS NANOSCIENCES, INC., Providence, RI (US)

(21) Appl. No.: 12/638,111

(22) Filed: Dec. 15, 2009

Related U.S. Application Data
(63) Continuation-in-part of application No. 11/215,678, filed on Aug. 29, 2005, now abandoned.
(60) Provisional application No. 60/679,104, filed on May 9, 2005.

(51) Int. Cl. H01L 31/00

(52) U.S. Cl. 136/256

(57) ABSTRACT

A method of using a dye sensitized solar cell includes providing a dye sensitized solar cell having a first electrode having a transparent substrate of a first refractive index, a second electrode having a second transparent substrate of a second refractive index comparable to the first refractive index, and an electrolyte solution in a gap between the first electrode and second electrode. The electrolyte solution is removed from the gap and replaced with an inert fluid having a third refractive index comparable to the first refractive index and the second refractive index to allow light to pass through the cell substantially unrefracted. Alternatively, the inert fluid is in the gap between the first electrode and second electrode, and the inert fluid is removed from the gap and replaced with an electrolyte solution.

### RELATED APPLICATIONS

The present application claims priority to and incorporates by reference U.S. application Ser. No. 11/215,678, filed Aug. 29, 2005, which claims priority to and incorporates by reference U.S. provisional application No. 60/679,104, filed May 9, 2005.

### FIELD OF THE INVENTION

The present invention relates generally to photovoltaic cells and, more specifically, to dye sensitized photovoltaic cells.

### BACKGROUND OF THE INVENTION

Photovoltaic cells, or solar cells, have long been used as energy sources. Traditional solar cells typically were constructed from a semiconductor, such as silicon. While photovoltaic cells employing semiconductors have proven to be effective energy sources for some applications, their fabrication and maintenance are expensive, making them cost-prohibitive in many applications.

In an effort to provide a more affordable photovoltaic cell, dye sensitized solar cells (DSSC) were developed utilizing inexpensive, transition metal electrodes incorporating dye-stuffs within the electrode to absorb solar radiation. In such a solar cell, the conversion of solar energy into electricity is achieved most efficiently when substantially all the emitted photons with wavelengths below 820 nm are absorbed. Such a solar cell having a porous titanium dioxide (TiO₂) substrate with a dye dispersed within the substrate to absorb light in the visible region of the spectrum is disclosed in U.S. Pat. No. 5,350,644 to Graetzel et al.

Dye sensitized solar cells generally include two spaced apart electrodes and an electrolyte solution. Typically, the first electrode includes a transparent conductive substrate coated with a TiO₂ porous matrix that includes a dyestuff. The second or counter electrode is typically a transparent conducting electrode with an optional platinum coating. Light passes through the transparent conductive substrate and is absorbed by the dye within the porous matrix. When the dye absorbs light, electrons in the dye transition from a ground state to an excited state in a process known as photoexcitation. The excited electron then can move from the dye to the conduction band in the TiO₂ matrix. This electron diffuses across the TiO₂ and reaches the underlying conductive transparent substrate. The electron then passes through the rest of the circuit returning to the second or counter electrode of the cell.

When the electron moves from the dye to the TiO₂, the dye changes oxidation state because it has fewer electrons. Before the dye can absorb another photon of light, the electron must be restored. The electrolyte provides an electron to the dye and in turn has its oxidation state changed. The electrolyte subsequently recovers an electron itself from the second or counter electrode in a redox reaction.

In order for light energy conversion to be efficient, the dyestuff, after having absorbed the light and thereby acquired an energy rich state, must be able to inject, with near unit quantum yield, an electron into the conduction band of the TiO₂ film. This is facilitated by the dye-stuff being attached to the surface of the TiO₂ through an interlocking group. This group provides the electronic coupling between the chromomorphic group of the dyestuff and the conduction band of the semiconductor. This type of electronic coupling generally requires interlocking, π-conducting substituents such as carboxylate groups, cyano groups, phosphate groups, or chelating groups with π-conducting character, such as oximes, dioximes, hydroxy quinolines, salicylates, and alpha keto enolates.

Dye sensitized solar cells, such as those disclosed in Graetzel's patent, have generated substantial interest as viable sources of solar energy because they are easily produced using relatively inexpensive materials, and therefore may be provided at lower cost than traditional semiconductor solar cells. Dye sensitized solar cells however, suffer from several drawbacks impeding their widespread commercial viability.

The primary deficiency is that dye sensitized solar cells are not as durable as semiconductor solar cells. Typically, dye sensitized solar cells remain efficient for only five to ten years. This lack of longevity is generally due to the instability of the electrolyte solution and the dyes in the cell. Specifically, durability problems include: the inherent photochemical instability of the sensitizer dye absorbed onto the TiO₂ electrode, as well as its interaction with the surrounding electrolyte; the chemical and photochemical instability of the electrolyte; the instability of the Pt-coating of the counter-electrode in the electrolyte environment; and the nature and the failure of the cell's seals to prevent the intrusion of oxygen and water from the ambient air and the loss of electrolyte solvent.

Further sources of degradation include photo-chemical or chemical degradation of the dye (such as adsorption of the dye, or replacement of ligands by electrolyte species or residual water molecules), direct band-gap excitation of TiO₂ (holes in the TiO₂ valence band act as strong oxidants), photo-oxidation of the electrolyte solvent, release of protons from the solvent (change in pH), catalytic reactions by TiO₂ and Pt, changes in the surface structure of TiO₂, dissolution of Pt from the counter-electrode, and adsorption of decomposition products onto the TiO₂ surface.

Previously, research has focused on developing a better seal to the cell, an electrolyte solution resistant to degradation (several polymer gels have been proposed), and a bleach-resistant dye. Such research has been limited to date in its effectiveness.

The present invention remedies these deficiencies without requiring that new chemical entities be developed.

### SUMMARY OF THE INVENTION

In one aspect, the invention relates to a method of using a dye sensitized solar cell. The dye sensitized solar cell includes a first electrode having a first transparent substrate of a first refractive index, and a second electrode having a second transparent substrate of a second refractive index. The second refractive index is comparable to the first refractive index. The dye sensitized solar cell also includes an electrolyte solution. The first electrode and the second electrode are arranged to define a gap, and the electrolyte solution is disposed in the gap. The electrolyte solution may be removed from the gap, and the gap may be filled with an inert fluid having a third refractive index comparable to the first refractive index and the second refractive index to allow light to pass through the cell substantially unrefracted.

In another aspect, the invention relates to a method of using a dye sensitized solar cell. The dye sensitized solar cell includes a first electrode having a first transparent substrate of a first refractive index, and a second electrode having a second transparent substrate of a second refractive index. The second refractive index is comparable to the first refractive index. The dye sensitized solar cell also includes an inert fluid having a third refractive index comparable to the first refractive index and the second refractive index to allow light to pass through the cell substantially unrefracted. The first electrode and the second electrode are arranged to define a gap, and inert fluid is disposed in the gap. The inert fluid may be removed from the gap, and the gap may be filled with an electrolyte solution.

Embodiments of the invention may include one or more of the following features. The first electrode may include a porous high surface area titanium dioxide layer. The first electrode may include a replaceable light absorbing dye, and/or the first electrode may be dyed with a replaceable light absorbing dye. The replaceable light absorbing dye may be flushed. The replaceable light absorbing dye may be flushed with a hypochlorite salt. The light absorbing dye may be exposed to visible light. The dye sensitized solar cell may include a re-sealable seal forming a fluid tight container between the first electrode and the second electrode.

### BRIEF DESCRIPTION OF THE DRAWINGS

These and other aspects of the invention are better understood with reference to the detailed description of the invention with reference to the figures, in which:

FIG. 1 is a cross-sectional elevational view of an embodiment of a photovoltaic cell of the present invention;

FIG. 2 is a flow chart of an embodiment of the steps of recharging the photovoltaic cell of FIG. 1 according to a method of the invention;

FIG. 3 is a graph of the results of multiple recharging of the cell of FIG. 1 utilizing the method of FIG. 2; and

FIG. 4 is a schematic representation of an embodiment of the recharging apparatus of the invention as disclosed herein.

### DETAILED DESCRIPTION OF THE INVENTION

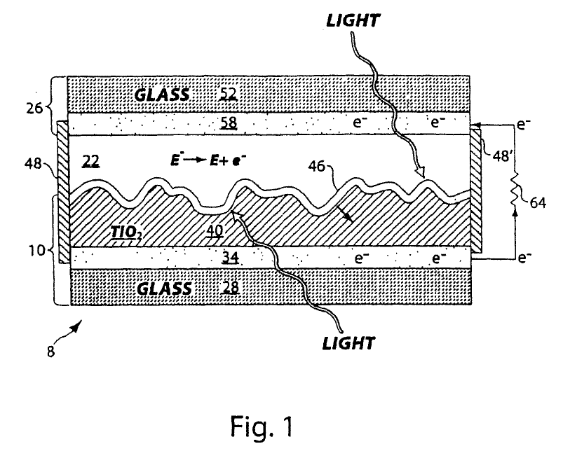

Dye sensitized solar cells (DSSC) are known in the art, and shown in U.S. Pat. No. 5,350,644 to Graetzel, which is incorporated by reference herein. Referring to FIG. 1, a photovoltaic cell 8 constructed in accordance with the invention is shown. The cell 8 generally includes two spaced apart electrodes 10, 16 and an electrolyte solution 22. The first electrode 10 includes a transparent conductive substrate such as glass 28 with a thin conductive film 34 and coated with a titanium dioxide (TiO₂) porous matrix 40 which includes a dyestuff 46. In one embodiment, the dye is N3(cis-bis(isothiocyanato)bis(2,2-bipyridyl-4,4′-dicarboxylato)ruthenium (II)) dissolved in ethanol. The second or counter electrode 16 is typically a transparent conducting electrode of a substrate, such as glass 52 coated with a thin conductive film 58 such as platinum. The gap between the two electrodes 10, 16 is filled with electrolyte 22. In one embodiment the electrolyte 22 is an Iodide electrolyte, such as an iodide based low viscosity electrolyte with 50 mM of tri-iodide. An example of such an electrolyte is solaronix Idolyte PN-50 from Solaronix SA, Rue d l'ouriette 129 CH-1170 Aubonne/Switzerland. The electrolyte 22 is maintained within the gap by a re-sealable seal 48, 48′.

Light passes through the transparent conductive substrates 28, 52 and is absorbed by the dye 46 within the porous matrix 40. When the dye 46 absorbs light, electrons in the dye 46 transition from a ground state to an excited state. The excited electron then can move from the dye 46 to the conduction band in TiO₂ matrix 40. This electron diffuses across the TiO₂ matrix 40 and reaches the underlying conductive transparent substrate 28. The electron then passes through the rest of the circuit 64 returning to the second or counter electrode 58 of the cell. In one embodiment the matrix 40 is nano-crystalline.

When the electron moves from the dye 46 to the TiO₂ matrix 40 the dye 46 changes oxidation state and before the dye 46 can absorb another photon of light, the electron must be restored. The electrolyte (E) 22 provides an electron to the dye 46 and has its own oxidation state changed. The electrolyte 22 subsequently recovers an electron from the second or counter electrode 16 in a redox reaction.

In the embodiment shown, the two glass electrodes 10, 16 provide two surfaces of the container that holds the electrolyte 22. An elastic material seal 48, 48′ formed to both electrodes completes the electrolyte 22 holding container. In one embodiment, the volume of the cell is 8×10⁻³ cm³. In the embodiment shown, the seal is an epoxy and acts as a septum, which can be penetrated by a hypodermic needle without leaking. In one embodiment, the epoxy is Stycast LT from Emerson & Cumming, 46 Manning Road, Billerica, Mass. In other embodiments, closable valves providing access through the seal are contemplated so that fluids can be introduced into and removed from the cell without requiring the seal be penetrated by a needle.

In the embodiment depicted, the dye-stuff is attached to the surface of the TiO₂ through an interlocking group of π-conducting substituents. In various embodiments, suitable substituents include carboxylate groups, cyano groups, phosphate groups, or chelating groups with π-conducting character, such as oximes, dioximes, hydroxy quinolines, salicylates, and alpha keto enolates.

In an embodiment, the TiO₂ is sintered on the first electrode. In an embodiment, the TiO₂ particles may be soaked with an oxidant, such as a sodium hypochlorite solution, prior to sintering. In another embodiment, the sodium hypochlorite solution is flushed by introducing a second solution to the substrate after soaking the TiO₂ particles.

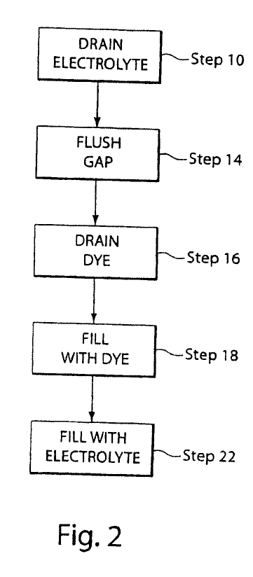

When the performance of the cell degrades over time, the cell can be recharged. A monitor may be used to determine when the cell is below a certain threshold requiring recharging. Referring also to FIG. 2, the first step (Step 10) is to drain the electrolyte solution. This may be accomplished by inserting a hypodermic needle through the re-sealable seals 48, 48′ and withdrawing the electrolyte 22. In an embodiment, the electrolyte is pushed out of the cell using a suitable solvent, such as acetonitrile, and the electrolyte and solvent are collected at a second port, such as resealable seal 48′. Next (Step 14) the remaining electrolyte 22 is flushed from the cell using acetonitrile. At this point, if only the electrolyte 22 is to be replaced, fresh electrolyte may be introduced into the gap through the re-sealable seal using the hypodermic needle. As used herein, the term flushing refers to the removal of a first substance from an area by the introduction of a second substance which carries the first substance out of the area.

If the dye 46 is also to be replaced, following the flushing of the electrolyte (Step 14), the light absorbing dye 46 is flushed (Step 16) from the matrix 40, using a first flushing solution, such as a hypochlorite salt solution, an aqueous ammonia, a sodium hydroxide solution, and a potassium hydroxide solution. In an embodiment, a second flushing solution may be used to flush the first flushing solution. In an embodiment, a new dye may be added without flushing the light absorbing dye. The old dye 46 is then replaced with a fresh dye 46, again through the re-sealable seal 48. In another embodiment, after an amount of time suitable for ensuring dyeing of the TiO₂ matrix, excess dye solution may be removed by a third solvent flush. At this time the electrolyte solution 22 can then be introduced into the cell through the re-sealable seal 48.

By the process of recharging and/or refilling, the dye sensitized solar cell may transition between photovoltaic and non-photovoltaic states. After flushing the electrolyte 22 and, optionally, any remaining light absorbing dye 46, the cell becomes a temporarily transparent, dual-paned window. Instead of replacing or refilling the electrolyte 22 and light absorbing dye 46, the cell may be filled with a clear or tinted inert fluid to allow the cell to function as non-photovoltaic window. A low volatility, index-matching fluid may eliminate reflection off the substrate surface(s). The index of refraction, a measure of the reduction of the speed of light through a medium, should be the same or comparable, preferably a difference less than about 0.1-0.3, for both the inert fluid and the transparent substrates to allow light to pass through the window substantially unrefracted. For example and without limitation, when the transparent substrate is glass, the inert fluid may be water. The inert fluid, like the electrolyte 22 and light absorbing dye 46, may be flushed and replaced with the same or different inert fluid, optionally of a different tint or color. Alternatively, an inert fluid in the cell may be flushed and replaced with electrolyte 22 and light absorbing dye 46, thereby converting the non-photovoltaic window back into a dye sensitized solar cell. Thus, a dye sensitized solar cell may transition between photovoltaic and non-photovoltaic states.

Dual photovoltaic and non-photovoltaic capabilities may improve both the efficiency and aesthetics of dye sensitized solar cells. For example, such a cell may be flushed and converted on a daily basis to perform a photovoltaic function during the day and, when the sunlight subsides, an aesthetic function during the night, such as a clear window through which the constellations of stars may be observed.

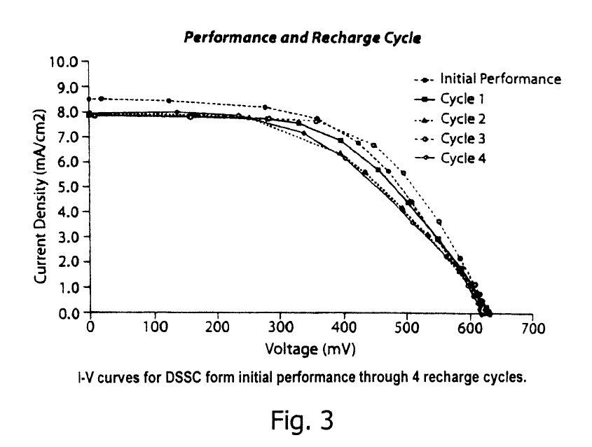

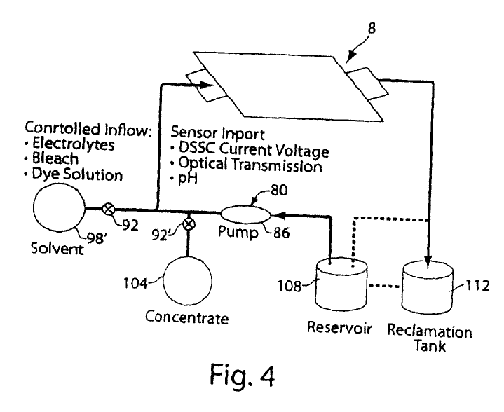

Referring to FIG. 3, a graph of the results of the current density of the cell plotted against voltage over multiple cycles of cleaning and dying is depicted. As can be seen, multiple cycles produce substantially identical results when compared to the initial performance of the cell. Referring to FIG. 4, a continuous system for removing old fluid constituents of the cell and replacement with new constituents is depicted. In the embodiment shown a sensor connected to a processor 80 monitors the conditions in the cell or group of cells 8. Such conditions can include the output current or voltage of the cell, a measure of optical transmission through the cell, or the pH of the cell among other parameters. When the cell's condition is determined to be below a predetermined set point, the processor uses a pump 86 and a series of valves 92 to pump the various solvents, dyes and bleaches from their reservoirs 98, 104, 108 into the cell 8 and remove various components into a reclamation tank 112, in the order as required by the steps of FIG. 2.

Although the invention has been described in terms of its embodiments, one skilled in the art will be aware that certain changes are possible which do not deviate from the spirit of the invention and it is the intent to limit the invention only by the scope of the claims.

What is claimed is:

1. A method of using a dye sensitized solar cell comprising the steps of:
providing a dye sensitized solar cell comprising a first electrode having a first transparent substrate of a first refractive index, a second electrode having a second transparent substrate of a second refractive index comparable to the first refractive index, and an electrolyte solution, the first electrode and the second electrode arranged to define a gap and the electrolyte solution disposed in the gap;
removing the electrolyte solution from the gap; and
filling the gap with an inert fluid having a third refractive index comparable to the first refractive index and the second refractive index to allow light to pass through the cell substantially unrefracted.

2. The method of claim 1 wherein the first electrode comprises a porous high surface area titanium dioxide layer.

3. The method of claim 1 wherein the first electrode comprises a replaceable light absorbing dye.

4. The method of claim 3 further comprising the step of flushing the replaceable light absorbing dye.

5. The method of claim 4 wherein the step of flushing comprises flushing the replaceable light absorbing dye with a hypochlorite salt.

6. The method of claim 1 further comprising the step of dying the first electrode with a replaceable light absorbing dye.

7. The method of claim 1 further comprising exposing the dye sensitized solar cell to visible light.

8. The method of claim 1 wherein the dye sensitized solar cell further comprises a resealable seal forming a fluid tight container between the first electrode and the second electrode.

9. A method of using a dye sensitized solar cell comprising the steps of:
providing a dye sensitized solar cell comprising a first electrode having a first transparent substrate of a first refractive index, a second electrode comprising a second transparent substrate of a second refractive index comparable to said first refractive index, and an inert fluid having a third refractive index comparable to the first refractive index and the second refractive index to allow light to pass through the cell substantially unrefracted, the first electrode and the second electrode arranged to define a gap and the inert fluid disposed in the gap;
removing the inert fluid from the gap; and
filling the gap with an electrolyte solution.

10. The method of claim 9 wherein the first electrode comprises a porous high surface area titanium dioxide layer.

11. The method of claim 9 wherein the first electrode comprises a replaceable light absorbing dye.

12. The method of claim 11 further comprising the step of flushing the replaceable light absorbing dye.

13. The method of claim 12 wherein the step of flushing comprises flushing the replaceable light absorbing dye with a hypochlorite salt.

14. The method of claim 9 further comprising the step of dying the first electrode with a replaceable light absorbing dye.

15. The method of claim 9 further comprising exposing the dye sensitized solar cell to visible light.

16. The method of claim 9 wherein the dye sensitized solar cell further comprises a resealable seal forming a fluid tight container between the first electrode and the second electrode.
